(19) United States
(12) Patent Application Publication
(10) Pub. No.: US 2024/0399536 A1
(43) Pub. Date: Dec. 5, 2024

(54) EDDY CURRENT SENSOR, EDDY CURRENT SENSOR ASSEMBLY, AND POLISHING APPARATUS

(71) Applicant: EBARA CORPORATION, Tokyo (JP)

(72) Inventors: Katsuya MINATOZAKI, Tokyo (JP); Taro TAKAHASHI, Tokyo (JP)

(21) Appl. No.: 18/673,104

(22) Filed: May 23, 2024

(30) Foreign Application Priority Data
May 31, 2023 (JP) 2023-089987

(51) Int. Cl. B24B 49/10; B24B 37/013; G01N 27/90; H01L 21/304

(52) U.S. Cl. CPC B24B 49/105; B24B 37/013; G01N 27/9006; H01L 21/304

(57) ABSTRACT

Provided is an eddy current sensor having an improved sensitivity in a detection coil of the eddy current sensor compared with a conventional one. An eddy current sensor (210) includes a magnetic material, a detection coil (34), a correction coil (166), and an excitation coil. The excitation coil is wound to surround the first pillar and/or the external wall of the magnetic material and generates an eddy current in a conductive film. The detection coil (34) and the correction coil (166) are wound to surround the first pillar and/or the external wall and detects a change in the eddy current generated in the conductive film. An amount of change in an output signal of the correction coil (166) when the eddy current generated in the conductive film changes is less than an amount of change in an output signal of the detection coil (34). One end of the correction coil (166) is directly connected to one end of the detection coil (34), and another end of the correction coil and another end of the detection coil are directly connected to an impedance converter (124) or an amplifier.

### TECHNICAL FIELD

The present invention relates to an eddy current sensor, an eddy current sensor assembly, and a polishing apparatus.

### BACKGROUND ART

An eddy current sensor is used for film thickness measurement, displacement measurement, and the like. The following describes the eddy current sensor using the film thickness measurement as an example. An eddy current sensor for film thickness measurement is used, for example, in a manufacturing process (a polishing process) of a semiconductor device. The eddy current sensor is used in the polishing process as follows. It is necessary to planarize a surface of a semiconductor wafer as an object to be polished in the manufacturing process of the semiconductor device, and as a way of this planarization method, a chemical mechanical polishing (CMP) apparatus has been used for polishing.

In chemical mechanical polishing (CMP), while a polishing liquid is being supplied to a polishing pad disposed on a polishing table that rotates, a workpiece (wafer) is rotated by a polishing head and the wafer is pressed against the polishing pad, and thus, the wafer is polished. In order to determine whether a substrate is polished to an appropriate film thickness or not, that is, whether the polishing has reached the end point or not, there sometimes is provided an eddy-current type film thickness sensor (hereinafter, referred to as an eddy current sensor) in the polishing table.

The eddy current sensor is used in film thickness measurement of a conductive film (for example, a metallic film) that exists on the substrate. The eddy current sensor has an excitation coil that generates a magnetic flux. The eddy current sensor generates an eddy current in the conductive film by overlapping (interlinking) a part of the generated magnetic flux over the conductive film of the substrate. The generated eddy current is detected by a detection coil. The film thickness of the conductive film is determined based on the detected eddy current.

The related art described in PTL 1 detects a difference between output signals of a detection coil and a dummy coil using a bridge circuit configured of a variable resistor. The difference between the output signals is amplified by an amplifier for high frequency (RF amplifier). However, there are problems as described below.
Noise is increased by the RF amplifier.
As the result of a change in a resistance value caused by an environmental change, such as a temperature, the difference between the output signals varies (for example, saturates), and readjustment of the bridge circuit and the like is necessary.

### CITATION LIST

### Patent Literature

PTL 1: Japanese Unexamined Patent Application Publication No. 2017-152471

### SUMMARY OF INVENTION

### Technical Problem

One configuration of the present invention has been made to solve such problems, and the purpose thereof is to provide an eddy current sensor having an improved sensitivity in a detection coil of the eddy current sensor compared with a conventional one.

### Solution to Problem

In order to solve the above-described problem, a first configuration employs an eddy current sensor that includes a magnetic material, an excitation coil, a detection coil, and a correction coil. The magnetic material includes a bottom, a first pillar extending from a center of the bottom, and an external wall extending from a periphery of the bottom. The excitation coil is wound to surround the first pillar and/or the external wall. The excitation coil generates an eddy current in a conductive film. The detection coil and the correction coil are wound to surround the first pillar and/or the external wall. The detection coil and the correction coil detect a change in the eddy current generated in the conductive film. An amount of change in an output signal of the correction coil when the eddy current generated in the conductive film changes is less than an amount of change in an output signal of the detection coil. One end of the correction coil is directly connected to one end of the detection coil, and another end of the correction coil and another end of the detection coil are directly connected to an impedance converter or an amplifier.

Since a bridge circuit configured of a variable resistor is not used, the embodiment reduces the necessity of readjustment of the bridge circuit and the like caused by the difference between the output signals being saturated as the result of a change in a resistance value. The saturation of the output signals is reduced compared with a conventional one, and therefore, it is possible to provide the eddy current sensor having an improved sensitivity of the detection coil of the eddy current sensor compared with the conventional one.

A second configuration employs the eddy current sensor according to Configuration 1 in which the detection coil has a cross-sectional area larger than a cross-sectional area of the correction coil, and/or the detection coil has a count of turns more than a count of turns of the correction coil, and/or a distance from the detection coil to the bottom is longer than a distance from the correction coil to the bottom.

A third configuration employs the eddy current sensor according to Configuration 1 or 2 in which the external wall surrounds an outer periphery of the first pillar.

A fourth configuration employs the eddy current sensor according to Configuration 1 or 2 in which the bottom is in a bar shape, and the external wall includes a second pillar and a third pillar disposed at respective both ends of the bar shape.

A fifth configuration employs the eddy current sensor according to any one of Configurations 1 to 4 in which the correction coil and the detection coil have winding directions in opposite directions.

A sixth configuration employs the eddy current sensor according to any one of Configurations 1 to 5 in which the excitation coil and the detection coil are both disposed in an opposite side of the bottom in a direction in which the first pillar extends.

A seventh configuration employs the eddy current sensor according to Configuration 4 in which the correction coil is wound around the second pillar and the third pillar.

An eighth configuration employs the eddy current sensor according to Configuration 7 in which the detection coil and the correction coil have winding directions in a same direction.

A ninth configuration employs the eddy current sensor according to any one of Configurations 1 to 8 in which the detection coil and the correction coil are configured of one continuous conductive line, a part of the one conductive line is the detection coil, and another part of the one conductive line is the correction coil.

A tenth configuration employs an eddy current sensor assembly that includes the eddy current sensor according to any one of Configuration 1 or 9 and the impedance converter or the amplifier.

An eleventh configuration employs a polishing apparatus that includes a polishing pad, a polishing table, the eddy current sensor, the impedance converter or the amplifier, and a detected signal processing circuit. The polishing pad has a polishing surface for polishing the conductive film. The polishing pad is mounted to the polishing table. The eddy current sensor is according to Configuration 1 or 9 disposed in the polishing table. The detected signal processing circuit is configured to calculate film thickness data of the conductive material from an output of the impedance converter or the amplifier.

### BRIEF DESCRIPTION OF DRAWINGS

FIG. 1 is a drawing schematically illustrating an overall configuration of a polishing apparatus;

FIG. 2 is a plan view illustrating a relation among a polishing table, an eddy current sensor, and a polishing object;

FIGS. 3A and 3B are drawings illustrating electrical connections of the eddy current sensor;

FIG. 4 is a drawing illustrating a bridge circuit used in a conventional analog signal processing circuit;

FIG. 5 is a drawing illustrating the conventional analog signal processing circuit;

FIGS. 6A, 6B, and 6C are drawings describing differences between the related art, a comparing circuit, and an embodiment of the present invention;

FIGS. 7A and 7B are drawings describing a problem of the comparing circuit;

FIG. 8 is a conceptual diagram of the eddy current sensor;

FIGS. 9A and 9B are cross-sectional views of the eddy current sensor;

FIGS. 10A, 10B, 10C, 10D, 10E, and 10F are drawings illustrating a magnetic material of the eddy current sensor;

FIGS. 11A, 11B, and 11C are drawings illustrating a voltage generated in both ends of a detection coil and a voltage generated in both ends of a correction coil;

FIG. 12 is a drawing illustrating a magnetic field of one embodiment;

FIGS. 13A and 13B are drawings illustrating, what is called, an E-type core;

FIGS. 14A, 14B, and 14C are drawings in which the eddy current sensor illustrated in FIGS. 13A and 13B is viewed from above;

FIG. 15 is a drawing illustrating a magnetic field of the embodiment illustrated in FIG. 13A;

FIG. 16 is a drawing illustrating a magnetic field of the embodiment illustrated in FIG. 13B;

FIGS. 17A, 17B, and 17C are drawings illustrating an E-type core;

FIGS. 18A and 18B are drawings in which the eddy current sensor illustrated in FIGS. 17A, 17B, and 17C is viewed from above;

FIG. 19 is a drawing illustrating a magnetic field of the embodiment illustrated in FIG. 17A;

FIG. 20 is a drawing illustrating a magnetic field of the embodiment illustrated in FIG. 17B;

FIG. 21 is a drawing illustrating an E-type core;

FIGS. 22A, 22B, and 22C are drawings illustrating widths of a first pillar; and

FIG. 23 is a drawing illustrating a magnetic field of the embodiment illustrated in FIG. 21.

### DESCRIPTION OF EMBODIMENTS

The following describes embodiments of the present invention with reference to the drawings. Note that, in each of the following embodiments, the same or equivalent members have the same reference numerals to omit overlapping descriptions in some cases. The features described in each embodiment are applicable to another embodiment as long as they do not conflict with one another.

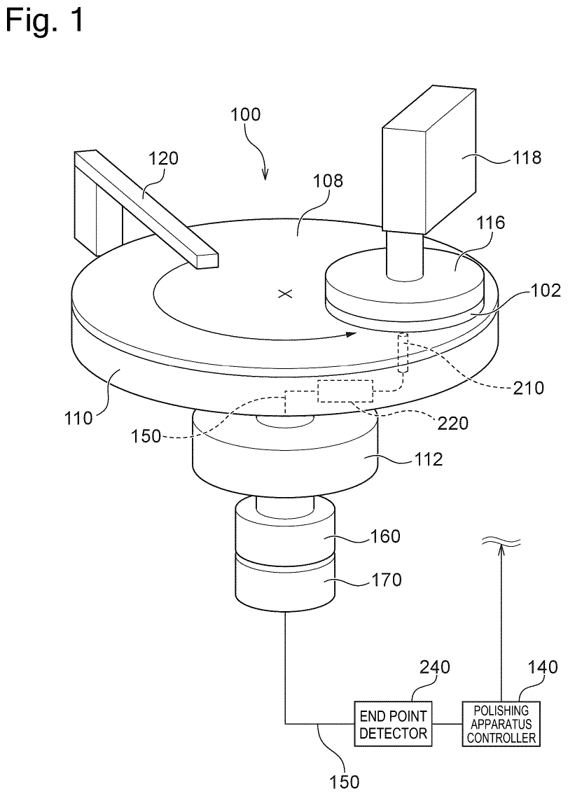

As illustrated in FIG. 1, a polishing apparatus 100 that polishes a polishing object 102 (a conductive film) includes a polishing table 110 having an upper surface on which a polishing pad 108 having a polishing surface for polishing the polishing object 102, such as a substrate or a wafer, is mountable, a first electric motor 112 that rotatably drives the polishing table 110, a top ring 116 allowed to hold the polishing object 102, and a second electric motor 118 that rotatably drives the top ring 116. The polishing object 102 is a detection object. The detection object is, for example, various kinds of conductive films formed on a substrate, such as a semiconductor wafer, or on a surface of the substrate. The polishing pad 108, the polishing table 110, the first electric motor 112, the top ring 116, and the second electric motor 118 configure a polisher that can polish the detection object.

The polishing apparatus 100 includes a slurry line 120 that supplies a polishing abrasive liquid containing an abrasive onto an upper surface of the polishing pad 108. The polishing apparatus 100 includes a polishing apparatus controller 140 that outputs various kinds of control signals regarding the polishing apparatus 100.

The polishing apparatus 100 supplies polishing slurry containing polishing abrasive grains from the slurry line 120 onto the upper surface of the polishing pad 108 when the polishing object 102 is polished, and rotatably drives the polishing table 110 with the first electric motor 112. The polishing apparatus 100 then presses the polishing object 102 held by the top ring 116 onto the polishing pad 108 in a state where the top ring 116 is rotated about a rotation axis eccentric from a rotation axis of the polishing table 110. This causes the polishing pad 108 holding the polishing slurry to polish and planarize the polishing object 102.

The polishing apparatus 100 includes an eddy current sensor 210 that can form an eddy current in the detection object and detect the formed eddy current, and a detected signal processing circuit 220 connected to the eddy current sensor 210. The detected signal processing circuit 220 outputs film thickness data 150, and the film thickness data 150 is output to an end point detector 240 via rotary joint connectors 160, 170 (or slip rings).

The description will be given of the eddy current sensor 210. The polishing table 110 and the polishing pad 108 are provided with holes through which the eddy current sensor 210 is passed from a back surface side of the polishing table 110. The eddy current sensor 210 is inserted in the hole formed in the polishing table 110. The detected signal processing circuit 220 in this embodiment is arranged within the polishing table 110. The detected signal processing circuit 220 may be integrated with the eddy current sensor 210.

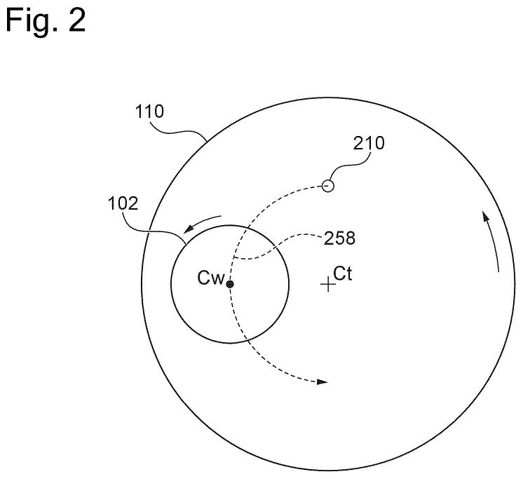

FIG. 2 is a plan view illustrating a relation among the polishing table 110, the eddy current sensor 210, and the polishing object 102. As illustrated in FIG. 2, the eddy current sensor 210 is disposed at a position that passes through a center Cw of the polishing object 102 held by the top ring 116 and being polished. The reference numeral Ct is a rotational center of the polishing table 110. For example, the eddy current sensor 210 is allowed to continuously detect a thickness of the polishing object 102 on a passing trajectory 258 (a scanning line) while the eddy current sensor 210 is passing below the polishing object 102.

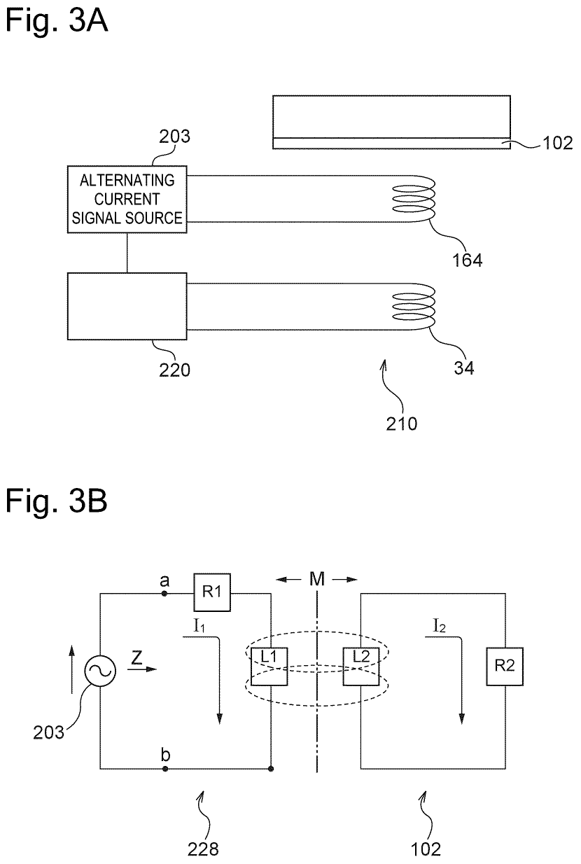

FIGS. 3A and 3B are drawings illustrating electrical connections of the eddy current sensor 210. FIG. 3A is a block diagram illustrating the electrical connections of the eddy current sensor 210, and FIG. 3B is an equivalent circuit diagram of the eddy current sensor 210.

As illustrated in FIG. 3A, the eddy current sensor 210 includes a detection coil 34 and an excitation coil 164 arranged in the proximity of a metallic film or the like in the polishing object 102. The excitation coil 164 is connected to an alternating current signal source 203. The details of the connections of the detection coil 34 and the excitation coil 164 to the alternating current signal source 203 and the detected signal processing circuit 220 will be described later. The polishing object 102 has, for example, a thin film of Cu, Al, Au, W, or the like formed on the semiconductor wafer. The detection coil 34 and the excitation coil 164 are arranged in the proximity of, for example, approximately 0.5 to 5.0 mm to the polishing object 102.

The eddy current sensor 210 has an impedance type that detects the conductive film based on a change in impedance viewed from the alternating current signal source 203 caused by the generation of the eddy current in the polishing object 102. That is, in the impedance type, an impedance Z changes by a change of an eddy current I₂ in the equivalent circuit illustrated in FIG. 3B, resulting in a change of the impedance Z viewed from the alternating current signal source (a fixed frequency oscillator) 203. The eddy current sensor 210 is allowed to detect this change of the impedance Z with the detected signal processing circuit 220, and thus allowed to detect the change of the conductive film.

The eddy current sensor of the impedance type extracts a real part I (a resistance component) of the impedance Z, an imaginary part Q (a reactance), a phase, and a synthetic impedance Z. Measurement information of the conductive film is obtained from frequency F, each of the impedance components Q, I, or the like. As illustrated in FIG. 1, the eddy current sensor 210 can be incorporated at a position near a surface inside the polishing table 110, and while it is positioned so as to oppose the polishing object 102 via the polishing pad, the change of the conductive film is detectable from the eddy current flowing in the polishing object 102.

The following more specifically describes the eddy current sensor of an impedance type with reference to FIG. 3B. The alternating current signal source 203 is an oscillator for fixed frequency of approximately 1 to 50 MHz, and for example, a crystal oscillator is used. An AC voltage supplied from the alternating current signal source 203 causes a current I₁ to flow in a sensor coil 260. The current flow in the sensor coil 260 arranged at the proximity of the polishing object 102 causes the magnetic flux generated from the sensor coil 260 to interlink with the polishing object 102. As the result, a mutual inductance M is formed between the sensor coil 260 and the polishing object 102, and an eddy current I₂ flows in the polishing object 102. Here, R1 is a resistor of a primary side 228 including the sensor coil 260, and L1 is a self-inductance of the primary side 228 including the sensor coil 260 similarly. On the polishing object 102 side, R2 is a resistor corresponding to an eddy-current loss, and L2 is a self-inductance of the polishing object 102. The impedance Z of the sensor coil 260 side viewed from the terminals a, b of the alternating current signal source 203 is changed by an effect of the magnetic line generated by the eddy current I₂.

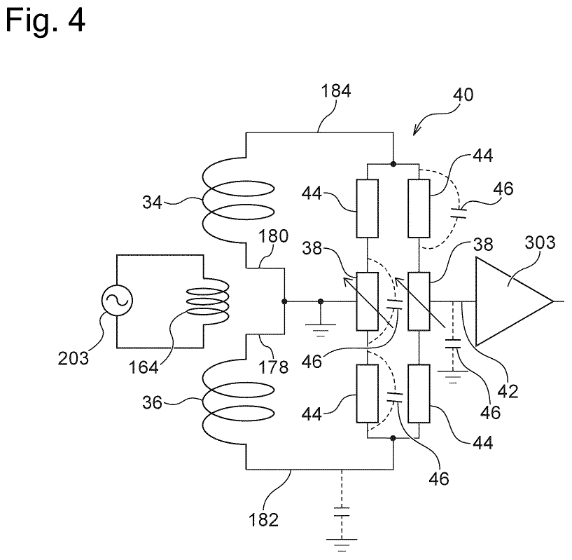

A conventional analog signal processing circuit that processes the detection signal of the eddy current sensor and detects the change of the impedance Z has a large noise, and the film thickness obtained by processing the detection signal of the eddy current sensor varies, and is unstable. Exemplary reason of unstable output in the conventional analog signal processing circuit will be described with reference to FIG. 4. FIG. 4 illustrates a bridge circuit used in the conventional analog signal processing circuit. The sensor coil 260 has the detection coil 34, a dummy coil 36, and the excitation coil 164. The detection coil 34 and the dummy coil 36 of the three coils configure a series circuit, and both ends thereof are connected to a resistor bridge circuit 40 including variable resistors 38. Adjusting the balance by adjusting the variable resistors 38 of the resistor bridge circuit 40 allows adjusting a zero point such that an output 42 of the resistor bridge circuit 40 becomes zero when the film thickness is zero.

Regarding a detection method using the conventional bridge circuit 40, a resistance value adjustment amount during the zero point adjustment is considerably small compared with the magnitude of the whole resistance value configuring the bridge circuit 40. As the result, a temperature change amount of the whole resistance value is a non-negligible amount compared with the resistance value adjustment amount during the zero point adjustment. Because of the changes in resistance values of the variable resistors 38 and fixed resistors 44 caused by a temperature change, the changes in floating capacitances 46 that the resistors have, and the like, the characteristics of the bridge circuit 40 are sensitively susceptible to the changes in surrounding environments of the resistors. As the result, the above-described zero point is easily shifted, and thus there lies a problem of reduced measurement accuracy of the film thickness.

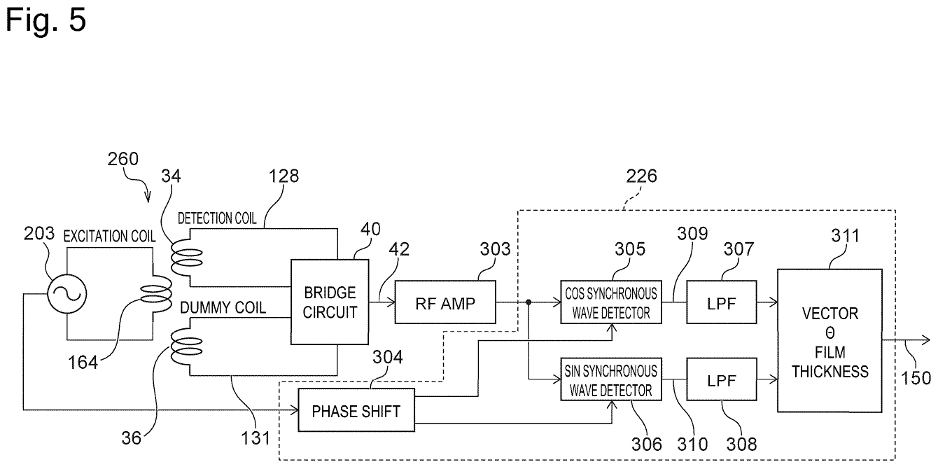

For comparing with the embodiment of this application, FIG. 5 illustrates the conventional analog signal processing circuit using the resistor bridge circuit 40. The sensor coil 260 has the detection coil 34, the dummy coil 36, and the excitation coil 164. The excitation coil 164 of the sensor coil 260 is connected to the alternating current signal source 203, which forms an eddy current in the polishing object 102 arranged at the proximity of the eddy current sensor 210 by generating an alternating magnetic flux. The signal source 203 supplying an alternating current signal to the sensor coil 260 arranged at the proximity of the polishing object 102 is an oscillator for a fixed frequency made of a crystal oscillator. The alternating current signal source 203 supplies a voltage of a fixed frequency of, for example, 1 to 50 MHz. The AC voltage formed by the signal source 203 is supplied to the excitation coil 164.

Signals 128, 131 output from terminals of the sensor coil are output as the output 42 through the resistor bridge circuit 40. The output 42 is input to a synchronous wave detector configured of a cos synchronous wave detector circuit 305 and a sin synchronous wave detector circuit 306 through a high-frequency amplifier 303. The synchronous wave detector extracts a cos component (Q component) and a sin component (I component) in the detection signal. Here, two signals, an in-phase component (0°) and a quadrature-phase component (90°) of the signal source 203, are formed from an oscillation signal formed in the signal source 203 by a phase shift circuit 304. These signals are respectively introduced to the sin synchronous wave detector circuit 306 and the cos synchronous wave detector circuit 305, and the above-described synchronous detection is performed.

Low-pass filters 307, 308 remove unnecessary high-frequency components of, for example, 5 KHz or more, that is the signal component or more from the signals that have undergone the synchronous detection. The signals that have undergone the synchronous detection are a Q component output 309 as a cos synchronous detection output and an I component output 310 as a sin synchronous detection output. An arithmetic circuit 311 performs a vector operation to obtain a magnitude of the impedance Z, (Q²+I²)^{1/2}, from the Q component output 309 and the I component output 310. The arithmetic circuit 311 performs θ processing to obtain a phase output (θ=tan⁻¹Q/I) from the Q component output 309 and the I component output 310, similarly. Here, these filters 307, 308 are disposed for removing a noise component of the sensor signal, and cutoff frequencies corresponding to the various kinds of filters are configured. A wave detection circuit 226 includes the phase shift circuit 304, the synchronous wave detector circuit 305, the synchronous wave detector circuit 306, the low-pass filters 307, 308, and the arithmetic circuit 311. At least one of the Q component output 309, the I component output 310, the magnitude of the impedance Z, and the phase output is the film thickness data 150.

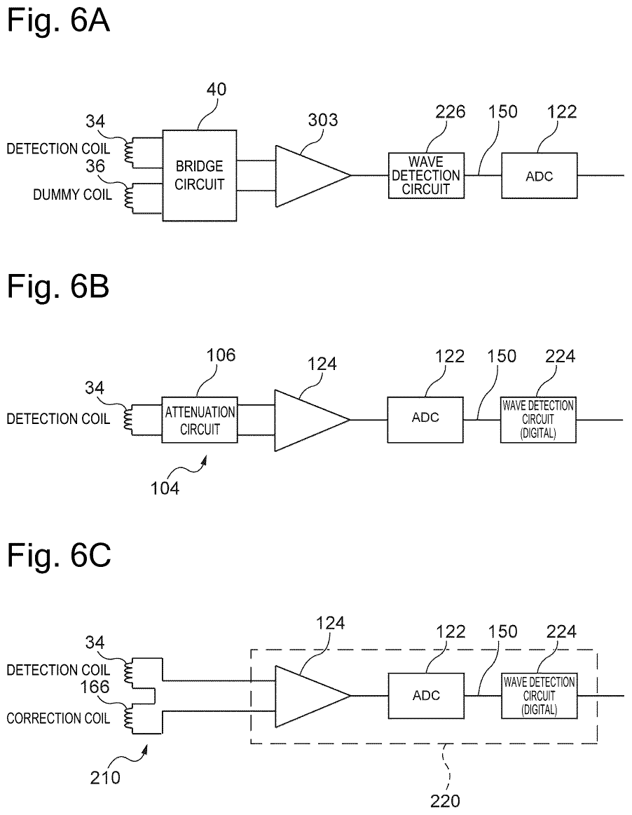

The related art illustrated in FIG. 5 has problems of, (1) requiring the high-frequency amplifier 303 having a large amplification factor, and the high-frequency amplifier 303 increases noise, and (2) requiring readjustment due to a varied (saturated) output from the resistor bridge circuit 40 caused by an environmental change, such as a temperature change, as described above. In order to improve these, there is considered a circuit that does not use the resistor bridge circuit 40 (hereinafter referred to as a “comparing circuit”). The comparing circuit will be described with reference to FIGS. 6A, 6B, and 6C.

FIGS. 6A, 6B, and 6C are drawings describing differences between the related art, the comparing circuit, and the embodiment of the present invention. FIG. 6A is a conventional analog signal processing circuit using the resistor bridge circuit 40 illustrated in FIG. 5. FIG. 6B illustrates a comparing circuit 104. FIG. 6C illustrates one embodiment of the present invention. The comparing circuit 104 does not use the resistor bridge circuit 40, therefore not using the dummy coil 36 either. By using one coil of only the detection coil 34 and a high-performance analog-digital conversion circuit 122 (ADC) and digitalizing a wave detection circuit 224, a stability improvement and a noise improvement are achievable. The wave detection circuit 224 is a digital circuit or software having a function equal to that of the wave detection circuit 226.

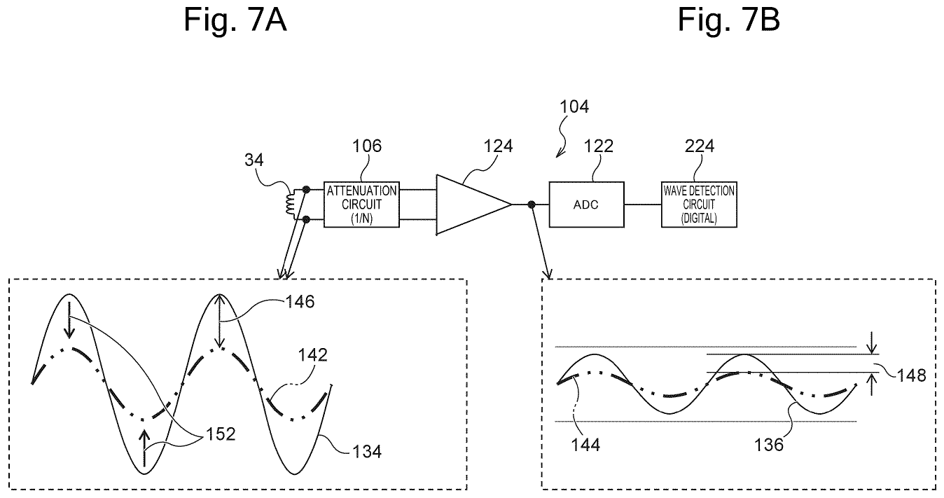

The comparing circuit 104 has a problem that the detection signal of the detection coil 34 is not able to be increased, and the sensitivity improvement is insufficient. This problem will be described with reference to FIGS. 7A and 7B. FIGS. 7A and 7B are drawings describing the problem of the comparing circuit. The comparing circuit 104 converts a magnetic field generated in the conductive film of the measurement target by an excitation coil (not illustrated) of the eddy current sensor into a voltage by the detection coil 34 as a receiver coil of the eddy current sensor. The output of the detection coil 34 is input to an attenuation circuit 106, and an amplitude is decreased. Thereafter, the signal has its impedance converted by an impedance converter 124. The impedance converter 124 has an amplification factor of approximately 1. The signal whose impedance has been converted is converted into a digital signal by the analog-digital conversion circuit 122, and thereafter, is input to the wave detection circuit 224. FIG. 7A illustrates a voltage appearing in both ends of the detection coil 34. FIG. 7B is an output signal of the impedance converter 124. FIGS. 7A and 7B have time (unit is second: s) on the horizontal axis and voltage (unit is millivolt: mv) on the vertical axis.

When the eddy current sensor moves to the proximity of the conductive film from a position apart from the conductive film, the voltage output by the detection coil 34 changes in association with the movement. A difference between the output 134 of the detection coil 34 when the eddy current sensor is at the position apart from the conductive film and the output 142 of the detection coil 34 when the eddy current sensor is at the proximity of the conductive film is conductive film detection signals 146, 148. The conductive film detection signal depends also on the thickness of the conductive film when the eddy current sensor is at the proximity of the conductive film. The polishing progress status is determined from the temporal variation in the output of the detection coil 34 when the eddy current sensor 210 is under the polishing object 102 (see FIG. 2). FIGS. 7A and 7B illustrate outputs 134, 136 of the detection coil 34 when the eddy current sensor is at a position apart from the conductive film and outputs 142, 144 of the detection coil 34 when the eddy current sensor is at the proximity of the conductive film. FIGS. 7A and 7B illustrate the conductive film detection signals 146, 148 as well. By detecting the conductive film, the output signal of the detection coil 34 changes as arrows 152 indicate from the outputs 134, 136 to the outputs 142, 144. Since the conductive film becomes thinner in association with the polishing progress, the amplitudes of the conductive film detection signals 146, 148 decrease.

In order to increase the detection sensitivity of the film thickness, it is required to increase the sensitivity of the detection coil 34 by sensitivity improvement measures, such as increased number of turns of the detection coil 34 in the comparing circuit 104. When the sensitivity of the detection coil 34 is attempted to be increased, the detected signal has a larger amplitude than that of the related art as the resistor bridge circuit 40 is not used. However, the detectable voltage range is determined in the wave detection circuit 224 or the like subsequent to the detection coil 34, and it is required to add the attenuation circuit 106 when this range is exceeded. Therefore, the comparing circuit 104 is provided with the attenuation circuit 106. There lies a problem that the voltage attenuation cancels the sensitivity improvement measures of the eddy current sensor resulting in failure of increasing the detection sensitivity of the conductive film thickness.

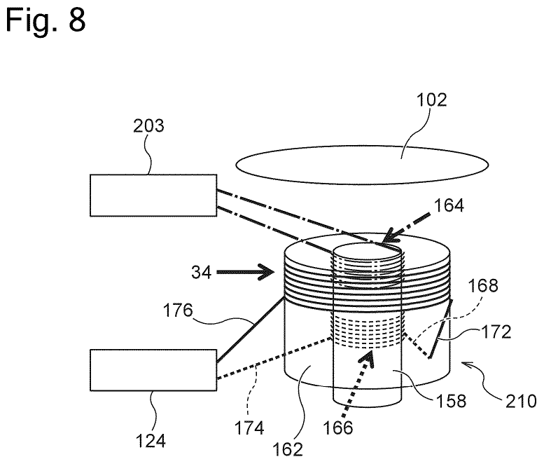

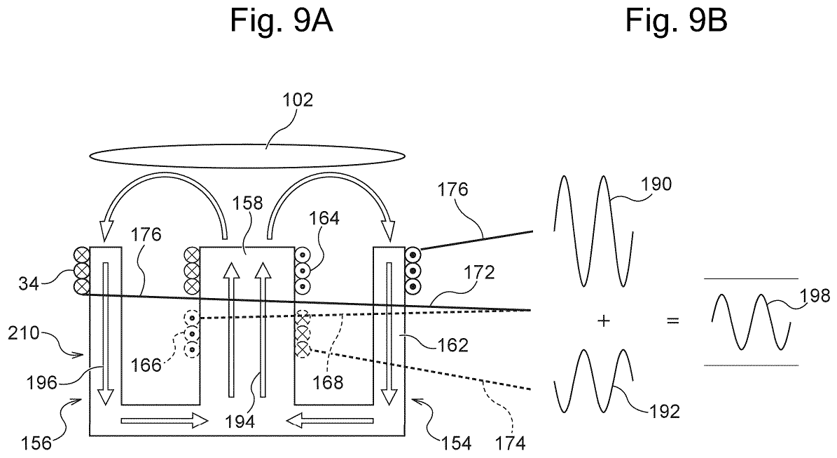

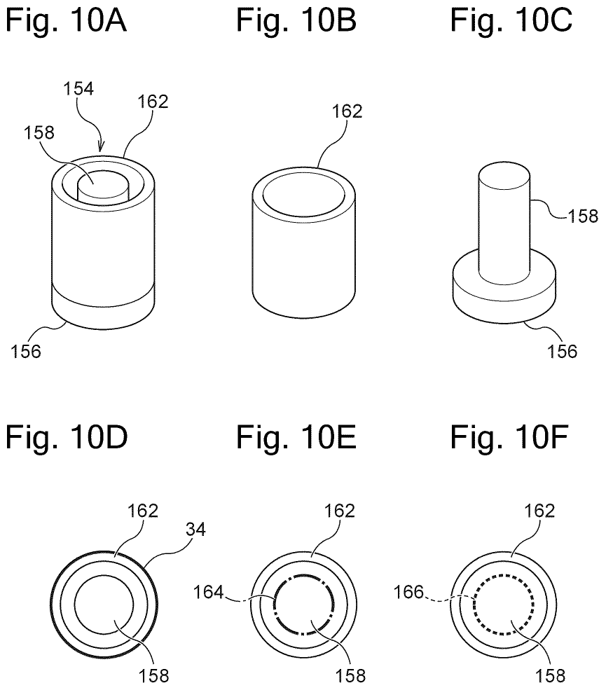

In one embodiment of the present invention illustrated in FIG. 6C, in order to solve the problems of the related art and the problem of the comparing circuit, the detection coil 34 that is likely to react to the conductive film and a correction coil 166 that is less likely to react to the conductive film are combined so as to increase the detection signal component. This further improves the sensitivity compared with the related art and the comparing circuit. The detail of the eddy current sensor 210 according to the one embodiment of the present invention is illustrated in FIGS. 8, 9A, 9B, 10A, 10B, 10C, 10D, 10E, and 10F. FIG. 8 is a conceptual diagram of the eddy current sensor 210. FIGS. 9A and 9B are cross-sectional views of the eddy current sensor 210. FIGS. 10A, 10B, 10C, 10D, 10E, and 10F are drawings illustrating a magnetic material 154 of the eddy current sensor 210. In FIG. 8, the magnetic material 154 is partly omitted for describing the arrangement of the coils.

The eddy current sensor 210 has the magnetic material 154. The magnetic material 154 includes a bottom 156, a first pillar 158 extending from the center of the bottom 156, and an external wall 162 extending from the periphery of the bottom 156. The external wall 162 surrounds the outer periphery of the first pillar 158, that is, the magnetic material 154 is, what is called, a pod-shaped core. As described later, the magnetic material 154 may be, what is called, an E-type core. The eddy current sensor 210 has the excitation coil 164, the detection coil 34, and the correction coil 166. The excitation coil 164 is wound to surround the first pillar 158 and/or the external wall 162 in the present invention, and generates an eddy current in the polishing object 102 (the conductive film). The excitation coil 164 is wound only around the first pillar 158 in the embodiment.

The detection coil 34 and the correction coil 166 are wound to surround the first pillar 158 and/or the external wall 162 in the present invention, and detect the change in eddy current generated in the polishing object 102. The detection coil 34 is wound to surround the first pillar 158 and the external wall 162 in the embodiment. In other words, the detection coil 34 is wound to surround the external wall 162 surrounding the outer periphery of the first pillar 158. The correction coil 166 is wound to surround only the first pillar 158. The amount of change in the output signal of the correction coil 166 when the eddy current generated in the polishing object 102 is changed is less than the amount of change in the output signal of the detection coil 34.

A one end 168 of the correction coil 166 is directly connected to a one end 172 of the detection coil 34. The other end 174 of the correction coil 166 and the other end 176 of the detection coil 34 are directly connected to the impedance converter or the amplifier. In the embodiment, the other end 174 of the correction coil 166 and the other end 176 of the detection coil 34 are directly connected to the impedance converter 124. The excitation coil 164 is connected to the signal source 203. “The amount of change in the output signal of the correction coil 166 when the eddy current generated in the polishing object 102 is changed is less than the amount of change in the output signal of the detection coil 34” means that “the detection coil 34 is likely to react to the conductive film, and the correction coil 166 is less likely to react to the conductive film than the detection coil 34” in another words. It also means that “the detection coil 34 has high sensitivity to the conductive film, and the correction coil 166 is lower in sensitivity to the conductive film than the detection coil 34.”

Here, “directly connected” in “a one end 168 of the correction coil 166 is directly connected to a one end 172 of the detection coil 34. The other end 174 of the correction coil 166 and the other end 176 of the detection coil 34 are directly connected to the impedance converter or the amplifier” means that they are connected without a circuit element, such as a resistor. In the related art illustrated in FIG. 4, while a one end 178 of the dummy coil 36 is directly connected to a one end 180 of the detection coil 34, the other end 182 of the dummy coil 36 or the other end 184 of the detection coil 34 is not directly connected to the high-frequency amplifier 303. The other end 182 of the dummy coil 36 and the other end 184 of the detection coil 34 are connected to the high-frequency amplifier 303 via the fixed resistors 44 and the variable resistors 38.

“A one end 168 of the correction coil 166 is directly connected to a one end 172 of the detection coil 34” means that “the detection coil 34 and the correction coil 166 are configured of one continuous conductive line, and a part of the one conductive line is the detection coil 34 and another part of the one conductive line is the correction coil 166” in other words. Note that other expressions also include that “a one end of the correction coil 166 and a one end of the detection coil 34 configured of respective different conductive lines are connected.”

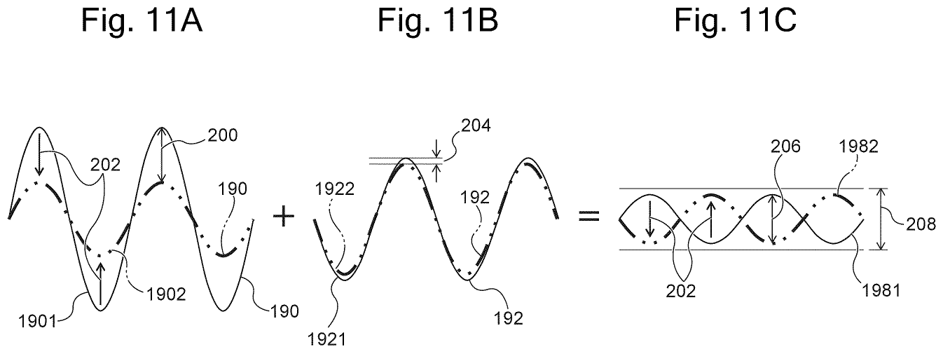

Various methods are possible to make the amount of change in the output signal of the correction coil 166 when the eddy current generated in the polishing object 102 is changed less than the amount of change in the output signal of the detection coil 34. The sensitivity of the coil increases as the cross-sectional area of the coil increases, increases as the number of turns of the coil increases, and increases as the distance between the coil and the conductive film decreases. Therefore, adjusting the cross-sectional area, the number of turns, or the distance allows adjusting the sensitivity. For example, the sensitivity may result to decrease even though the cross-sectional area is increased if the number of turns is reduced. Therefore, it is required to adjust the cross-sectional area, the number of turns, and the distance such that the sensitivity of the detection coil 34 becomes higher than the sensitivity of the correction coil 166. Note that, as illustrated in FIGS. 11A, 11B, and 11C described below, the magnitude of the sensitivity of the detection coil 34 has an upper limit in the system design, and the magnitude of the sensitivity of the correction coil 166 has a lower limit in the system design.

In the embodiment, the cross-sectional area of the detection coil 34 is larger than the cross-sectional area of the correction coil 166. Here, “the cross-sectional area” means the area of the cross section of the coil perpendicular to an axial direction of the coil. The cross-sectional area of the detection coil 34 is larger than the cross-sectional area of the correction coil 166, and therefore, the detection coil 34 is likely to react to the conductive film, and the correction coil 166 is less likely to react to the conductive film. In order to achieve “the detection coil 34 is likely to react to the conductive film, and the correction coil 166 is less likely to react to the conductive film,” “the number of turns of the detection coil 34 may be made more than the number of turns of the correction coil 166 and/or the distance from the detection coil 34 to the bottom 156 may be made longer than the distance from the correction coil 166 to the bottom 156.” “The distance from the detection coil 34 to the bottom 156 is made longer than the distance from the correction coil 166 to the bottom 156” means that “the distance from the detection coil 34 to the polishing object 102 is made shorter than the distance from the correction coil 166 to the polishing object 102” in another words.

In FIG. 8 to FIG. 10F, the external wall 162 surrounds the outer periphery of the first pillar 158, that is, the magnetic material 154 is, what is called, a pod-shaped core. As described later, the magnetic material 154 may be, what is called an E-type core. In the case of the E-type core, the bottom 156 is in a bar shape, and the external wall 162 includes a second pillar 186 and a third pillar 188 disposed respectively in both ends of the bar shape. FIG. 10A illustrates only the magnetic material 154. FIG. 10B illustrates only the external wall 162. FIG. 10C illustrates the bottom 156 and the first pillar 158. FIGS. 10D, 10E, and 10F are drawings in which the eddy current sensor 210 is viewed from above. FIGS. 10D, 10E, and 10F illustrate only respective locations of the detection coil 34, the excitation coil 164, and the correction coil 166 when they are viewed from above.

In FIG. 8 to FIG. 10F, the winding directions of the correction coil 166 and the detection coil 34 are opposite directions. However, the winding directions of the correction coil 166 and the detection coil 34 may be the same direction. In such a case, it is only necessary to invert the connecting terminals of the correction coil 166 and the detection coil 34 from FIG. 8. Note that, in FIG. 8 to FIG. 10F, the winding directions of the excitation coil 164 and the detection coil 34 are in the same direction. The correction coil 166 and the detection coil 34 are connected in series. When they are connected in series, whether the one end 168 of the correction coil 166 is connected to any of the one end 172 and the other end 176 of the detection coil 34 is configured such that a voltage 190 generated in both ends of the detection coil 34 and a voltage 192 generated in both ends of the correction coil 166 are inverted as illustrated in FIG. 9B, that is, such that the voltage 190 and the voltage 192 are cancelled one another.

As illustrated in FIGS. 9A and 9B, a magnetic field 194 that is generated by the excitation coil 164 and passes through the correction coil 166 is in an upward direction. The magnetic field that passes through the detection coil 34 includes the upward magnetic field 194 and a downward magnetic field 196, and the upward magnetic field 194 is stronger. In view of these two facts, as illustrated in FIG. 9B, inverting the winding direction causes the voltage 190 generated in both ends of the detection coil 34 and the voltage 192 generated in both ends of the correction coil 166 to be in reverse phase. Therefore, when the one end 168 of the correction coil 166 is connected to the one end 172 of the detection coil 34 as described above, a voltage 198 generated between the other end 174 of the correction coil 166 and the other end 176 of the detection coil 34 is a voltage in which the voltage 190 and the voltage 192 are cancelled one another as illustrated in FIG. 9B.

By thus combining the two coils (the detection coil 34 and the correction coil 166) invertedly to the magnetic field, the amplitude when the conductive film is not close to the two coils can be restricted within the measuring range of the receiving circuit (the impedance converter 124) while the reaction amplitude of the two coils when the conductive film comes close to the two coils can be maintained. That is, the attenuation circuit of the comparing circuit 104 is no longer necessary, and the signal when the conductive film is detected is not attenuated. This will be further described.

FIGS. 11A, 11B, and 11C illustrate the voltage 190 generated in both ends of the detection coil 34, and the voltage 192 generated in both ends of the detection coil 166. FIG. 11A illustrates the voltage 190 generated in both ends of the detection coil 34, a voltage 1901 is an amplitude when the conductive film is not close to the detection coil 34, and a voltage 1902 is an amplitude when the conductive film is close to the detection coil 34. FIG. 11B illustrates the voltage 192 generated in both ends of the correction coil 166, a voltage 1921 is an amplitude when the conductive film is not close to the correction coil 166, and a voltage 1922 is an amplitude when the conductive film is close to the correction coil 166. FIG. 11C illustrates the voltage 198 generated between the other end 174 of the correction coil 166 and the other end 176 of the detection coil 34, a voltage 1981 is an amplitude when the conductive film is not close to the two coils, and a voltage 1982 is an amplitude when the conductive film is close to the two coils. FIGS. 11A, 11B, and 11C have time (unit is second: s) on the horizontal axis, and voltage (unit is millivolt: mv) on the vertical axis.

Here “the coil is not close to the conductive film” means a reference state of the magnitude of the output signals of the detection coil 34 and the correction coil 166. That is, “the coil is not close to the conductive film” means, for example, the case where “the coil is away at a position where the coil is not affected by the conductive film as the polishing object 102.” For example, “a state where the top ring 116 in FIG. 1 is located outside the polishing table 110,” “a state where the top ring 116 is on the polishing table 110, but is sufficiently away from the eddy current sensor 210,” “a state where the eddy current sensor 210 is located immediately below the center of the top ring 116, but the top ring 116 does not hold a substrate or the top ring 116 holds a substrate having a conductive film with a predetermined film thickness,” or the like.

As the polishing table 110 rotates and the eddy current sensor approaches the conductive film, the output of the detection coil 34 changes in the directions of an arrows 202 from the voltage 1901 to the voltage 1902 as illustrated in FIG. 11A. A difference 200 between the voltage 1901 and the voltage 1902 is the amount of change that has been changed in the output signal caused by the detection coil 34 reacting to the conductive film. In association with the polishing progress, the conductive film becomes thinner, and therefore, the eddy current generated in the conductive film changes. That is, the difference 200 is decreased. “The amount of change in the output signal of the detection coil 34” is “the difference 200 or the amount of change in the difference 200 of the output signal of the detection coil 34 when the eddy current generated in the conductive film changes.”

As the polishing table 110 rotates and the eddy current sensor approaches the conductive film, the output of the correction coil 166 is changed from the voltage 1921 to the voltage 1922 as illustrated in FIG. 11B. The difference 204 between the voltage 1921 and the voltage 1922 is the amount of change that has been changed in the output signal caused by the correction coil 166 reacting to the conductive film. In association with the polishing progress, the conductive film becomes thinner, and therefore, the eddy current generated in the conductive film changes. That is, the difference 204 is decreased. “The amount of change in the output signal of the correction coil 166 when the eddy current generated in the conductive film changes” is “the difference 204 or the amount of change in the difference 204 of the output signal of the correction coil 166 when the eddy current generated in the conductive film changes.” The amount of change in the output signal of the correction coil 166 when the eddy current generated in the conductive film changes in this embodiment is less than the amount of change in the output signal of the detection coil 34. This can also be seen from the fact that the difference 204 is much smaller than the difference 200 when the difference 200 and the difference 204 are compared.

As the polishing table 110 rotates and the eddy current sensor approaches the conductive film, the difference between the output voltages of the detection coil 34 and the correction coil 166 is changed in the directions of the arrows 202 from the voltage 1981 to the voltage 1982 as illustrated in FIG. 11C. A difference 206 between the voltage 1981 and the voltage 1982 is the difference between the output voltages of the detection coil 34 and the correction coil 166 in which the amount of change has been changed in the output signal due to reaction with the conductive film. In association with the polishing progress, the conductive film becomes thinner, and therefore, the eddy current generated in the conductive film changes. The amount of change of the difference between the output voltages when the eddy current is changed means the amount of change of the difference 206.

In this embodiment, the detection coil 34 is wound to have a large cross-sectional area in order that a reversed magnetic field (that is, a magnetic field in a direction opposite of the magnetic field generated by the excitation coil 164) generated by the eddy current in the conductive film generated by the excitation coil 164 may be easily detected. The correction coil 166 is wound to have a small cross-sectional area so as to be less likely to be affected by the reversed magnetic field. The larger the distance from the conductive film to the coil is, the weaker the reversed magnetic field becomes, and therefore, the detection coil 34 is arranged in the upper side, and the correction coil 166 is arranged in the lower side. Such a “combination of the detection coil 34 and the correction coil 166” allows the voltage generated by the combination of the detection coil 34 and the correction coil 166 to be restricted to equal to or less than a measuring range 208 (inputtable range: see FIG. 11C) of the impedance converter 124 as a receiving circuit. Without attenuating the amount of change by the film reaction using the attenuation circuit 106 as in the comparing circuit 104, the voltage generated by the combination can be detected, that is, the sensitivity of the eddy current sensor 210 is increased. The advantageous effects of the embodiment include, as described above: a wide detection range of the receiving circuit can be used by directly connecting the sensors with different sensitivities to the impedance converter, not connecting to the attenuation circuit; environmental factors (temperature effect on the bridge circuit) that affect the measurement accuracy is avoidable; noise is improved as the direct connection is made to the impedance converter, not to the amplifier; and the detection sensitivity can be maximized because the excitation coil 164 and the detection coil 34 are both disposed near the polishing surface.

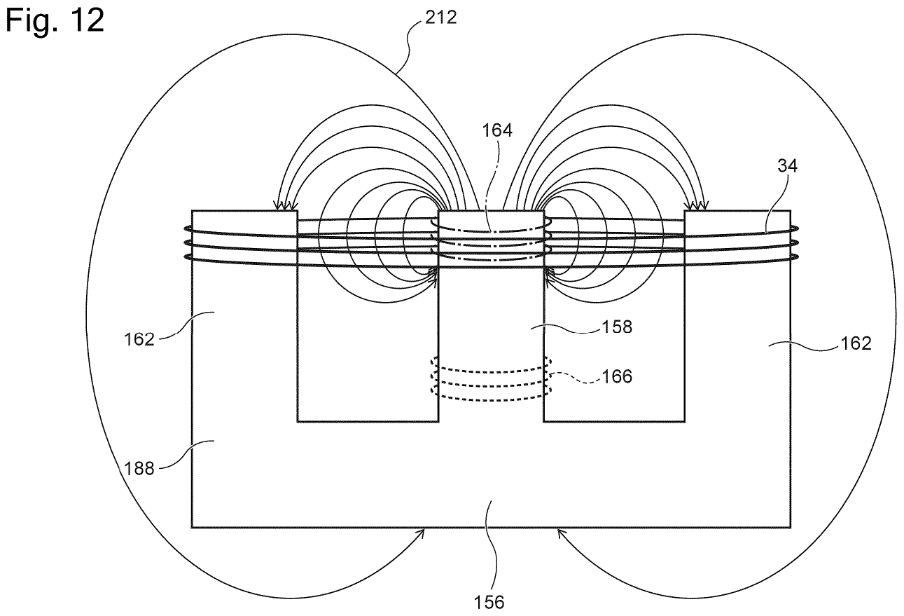

FIG. 12 illustrates a magnetic field 212 according to the embodiment. FIG. 12 is a drawing illustrating the magnetic field of the embodiment. Since the excitation coil 164 is arranged at a position close to the polishing object 102, a strong magnetic field is generated in the polishing object 102. Since the detection coil 34 is arranged at a position close to the polishing object 102, the output signal of the detection coil 34 increases.

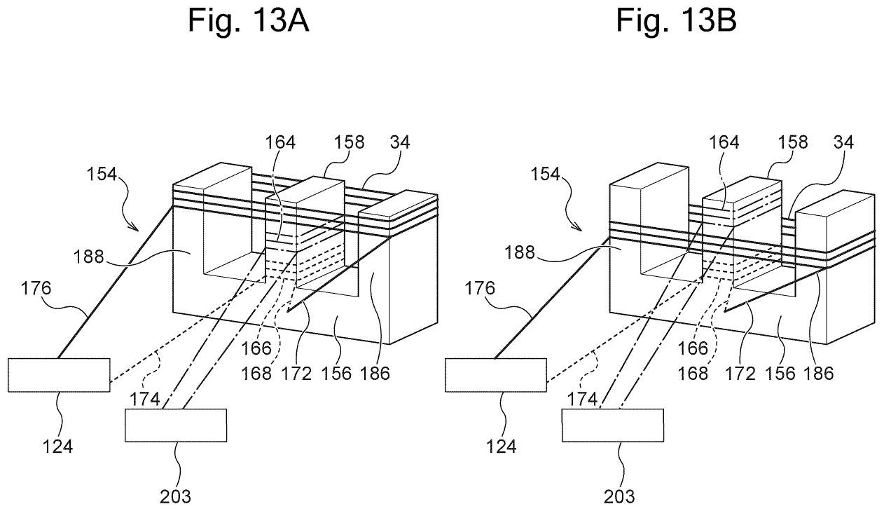

Another embodiment will be described with reference to FIGS. 13A and 13B. FIGS. 13A and 13B are drawings illustrating, what is called, an E-type core. The magnetic material 154 is an E-type core. In the case of the E-type core, the bottom 156 is in a square bar shape, the external wall 162 includes the second pillar 186 and the third pillar 188 in a square bar shape respectively disposed in both ends of the bar shape. The first pillar 158 is also in a square bar shape. The first pillar 158, the second pillar 186, the third pillar 188, and the bottom 156 are not limited to be in a square, and they may be round bars or may be in a polygon, such as a triangle and a pentagon. In FIG. 13A, the detection coil 34 is wound around the external wall 162. In the case of the embodiment, the external wall 162 are formed of the second pillar 186 and the third pillar 188. The detection coil 34 is wound around the entire outer periphery of the second pillar 186 and the third pillar 188. The detection coil 34 is arranged at a position closest to the polishing object 102. The correction coil 166 and the excitation coil 164 are wound around the first pillar 158. The excitation coil 164 is located in the middle between the detection coil 34 and the correction coil 166. The correction coil 166 is arranged at a position farthest from the polishing object 102 on the first pillar 158.

In FIG. 13B, the excitation coil 164 is arranged at a position closest to the polishing object 102. The detection coil 34 is wound around the external wall 162. That is, the detection coil 34 is wound around the entire outer periphery of the second pillar 186 and the third pillar 188. The correction coil 166 and the excitation coil 164 are wound around the first pillar 158. The detection coil 34 is located in the middle between the excitation coil 164 and the correction coil 166 in relation to the distance from the polishing object 102. The correction coil 166 is arranged at a position farthest from the polishing object 102 of the first pillar 158.

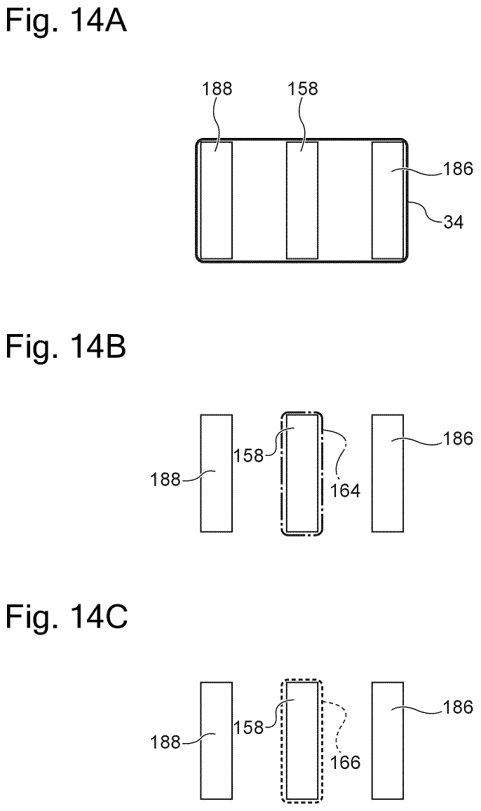

FIGS. 14A, 14B, and 14C are drawings in which the eddy current sensor 210 illustrated in FIGS. 13A and 13B is viewed from above. FIGS. 14A, 14B, and 14C illustrate only positions of the detection coil 34, the excitation coil 164, and the correction coil 166, respectively, when they are viewed from above.

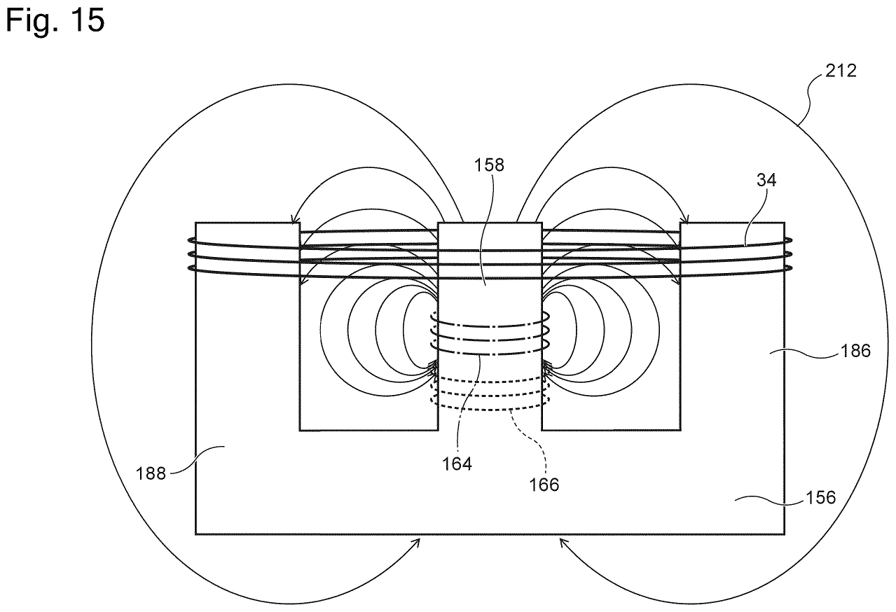

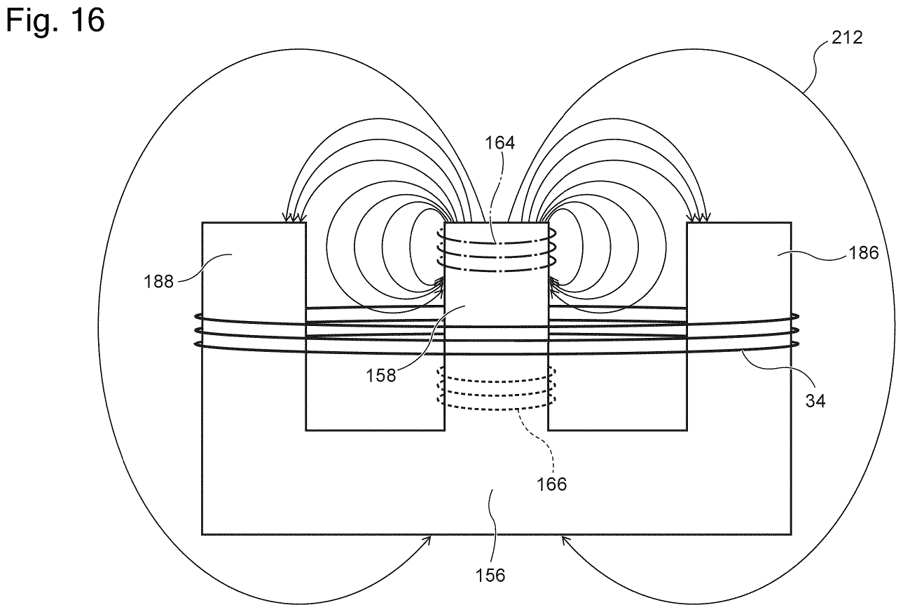

FIGS. 15 and 16 illustrate the magnetic field 212 of the embodiment illustrated in FIGS. 13A and 13B. FIGS. 15 and 16 are respective drawings illustrating the magnetic field of the embodiment illustrated in FIGS. 13A and 13B. By comparing FIG. 15 with FIG. 16, the excitation coil 164 is arranged at a position close to the polishing object 102 in FIG. 16, and therefore, a strong magnetic field is generated in the polishing object 102.

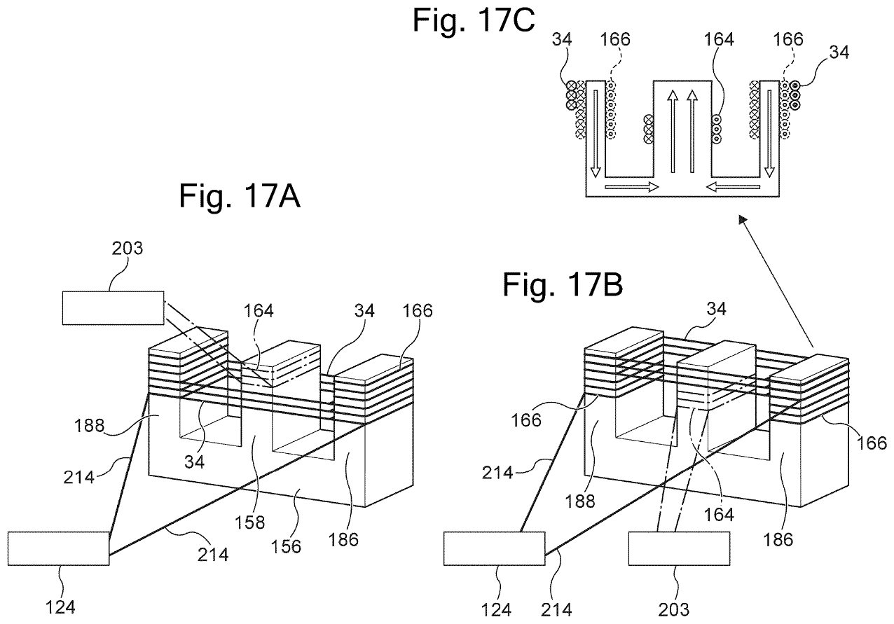

Another embodiment will be described with reference to FIGS. 17A, 17B, and 17C. FIGS. 17A, 17B, and 17C are drawings illustrating an E-type core. The magnetic material 154 is an E-type core, and has the same shape as the magnetic material 154 of the embodiment illustrated in FIGS. 13A and 13B. The correction coil is wound around the second pillar 186 and the third pillar 188. The winding directions of the detection coil and the correction coil are in the same directions as indicated by the signs of the distal ends and the roots of the arrows in FIG. 17C. The winding directions of the excitation coil 164 and the detection coil 34 are also in the same direction as illustrated in FIG. 17C. The detection coil 34 and the correction coil 166 are configured of one continuous conductive line, a part of the one conductive line is the detection coil 34, and the other part of the one conductive line is the correction coil 166.

The excitation coil 164 is located in the upper side in the drawing with respect to the detection coil 34 in FIG. 17A, that is, the excitation coil 164 is located close to the polishing object 102 with respect to the detection coil 34. The excitation coil 164 is located in the lower side in the drawing with respect to the detection coil 34 in FIG. 17B, that is, the excitation coil 164 is located far from the polishing object 102 with respect to the detection coil 34.

In the embodiment in FIGS. 17A, 17B, and 17C, the winding method of the detection coil 34 and the correction coil 166 is characteristic. In the embodiments so far, the detection coil 34 and the correction coil 166 are separate and independent coils. The embodiment in FIGS. 17A, 17B, and 17C achieves the same function as that of FIGS. 13A and 13B by the winding method (winding around a plurality of portions) not by dividing the detection coil 34 and the correction coil 166 into two types. Of one conducting wire 214, a part is the detection coil 34, and another part is the correction coil 166. The correction coil 166 of the conducting wire 214 is wound around each of the second pillar 186 and the third pillar 188, and the cross-sectional area of the correction coil 166 is the sum of the cross-sectional areas of the second pillar 186 and the third pillar 188. On the other hand, the detection coil 34 is wound around the outer periphery surrounding the first pillar 158, the second pillar 186, and the third pillar 188 as a whole body, and accordingly, the cross-sectional area of the detection coil 34 substantially corresponds to the cross-sectional area of the bottom 156.

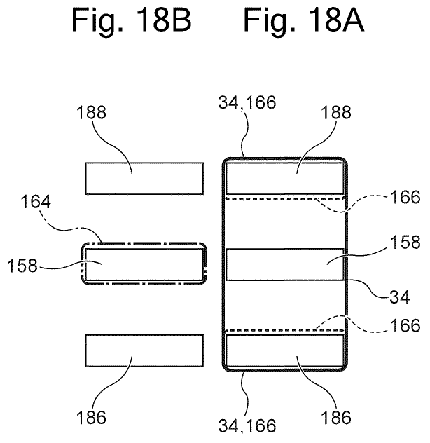

FIGS. 18A and 18B are drawings in which the eddy current sensor 210 illustrated in FIGS. 17A, 17B, and 17C is viewed from above. FIG. 18A illustrates only positions of the detection coil 34 and the correction coil 166 when they are viewed from above. FIG. 18B illustrates only a position of the excitation coil 164 when it is viewed from above. Note that as long as the positions where the correction coil 166 and the detection coil 34 are wound are those illustrated in FIGS. 17A, 17B, 17C, 18A, and 18B, the order of winding the correction coil 166 and the detection coil 34 around the second pillar 186 and the third pillar 188 may be in any order.

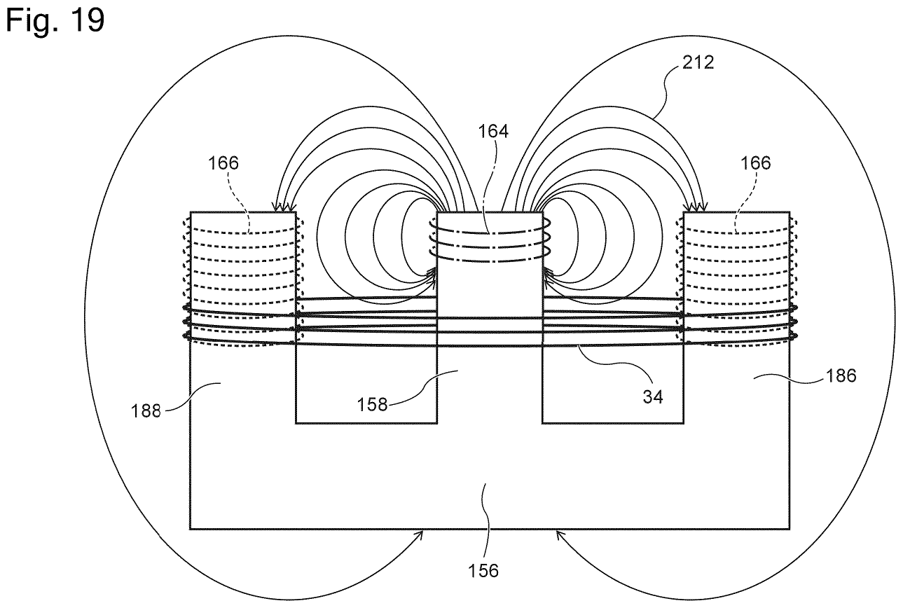

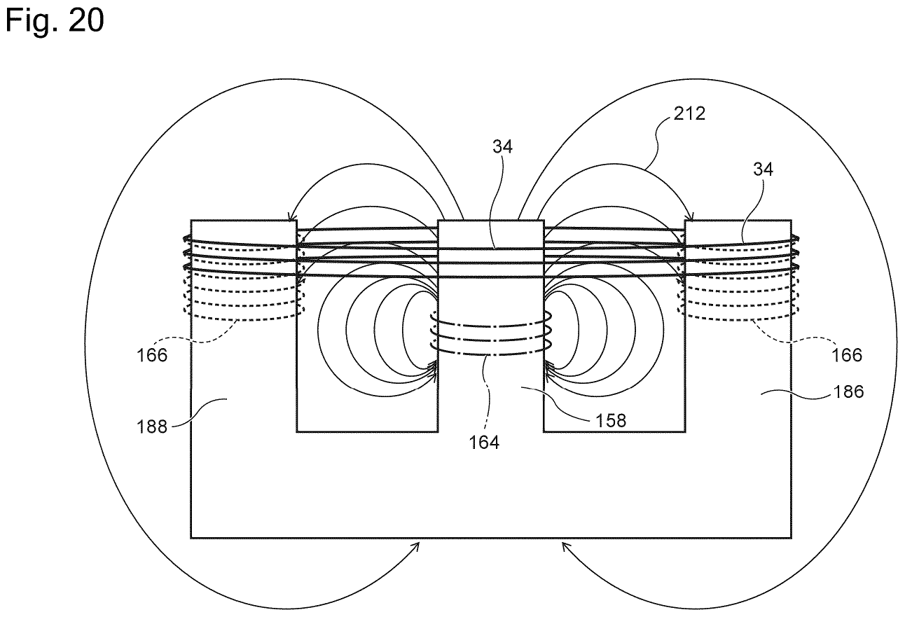

FIGS. 19 and 20 illustrate the magnetic field 212 of the embodiment illustrated in FIGS. 17A, 17B, and 17C. FIGS. 19 and 20 are respective drawings illustrating the magnetic field of the embodiment illustrated in FIGS. 17A and 17B. By comparing FIG. 19 with FIG. 20, since the excitation coil 164 is arranged at a position close to the polishing object 102 in FIG. 19, a strong magnetic field is generated in the polishing object 102 compared with FIG. 20.

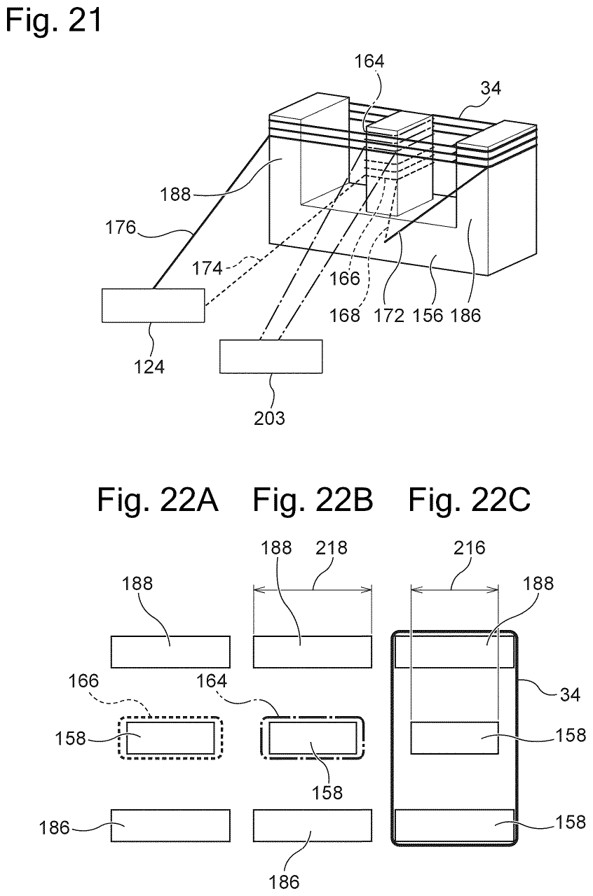

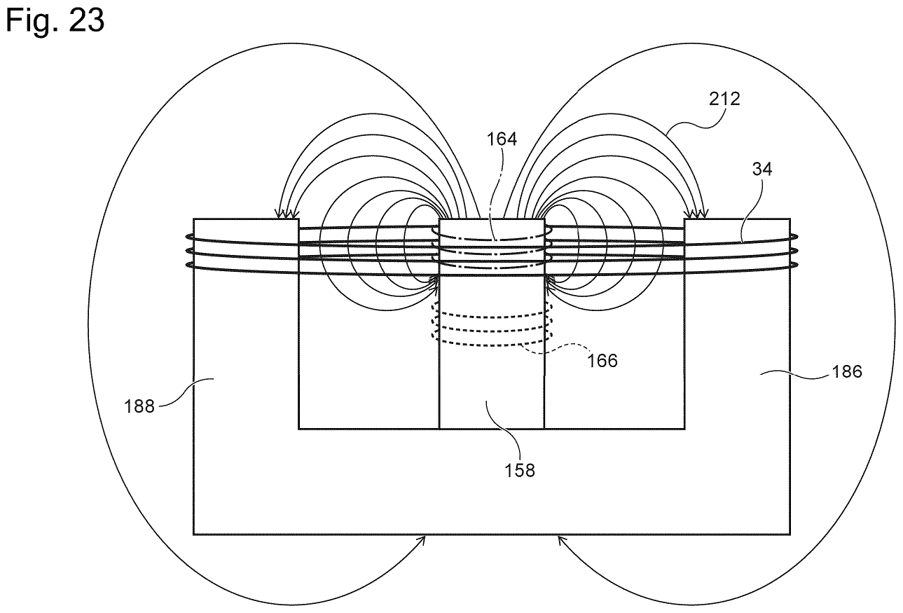

Another embodiment will be described with reference to FIG. 21. FIG. 21 is a drawing illustrating an E-type core. The magnetic material 154 is an E-type core. Only a center ferrite (the first pillar 158) of the magnetic material 154 has a reduced width, and the excitation coil 164 and the detection coil 34 have the same height. That is, the embodiment has, similarly to the embodiment in FIG. 8, the same distances between the polishing object 102 and the excitation coil 164 and between the polishing object 102 and the detection coil 34, and the excitation coil 164 and the detection coil 34 are at positions closest to the polishing object 102. The excitation coil 164 and the detection coil 34 are both disposed in an opposite side of the bottom 156 in a direction in which the first pillar 158 extends. FIG. 22C illustrates a width 216 of the first pillar 158. FIG. 22B illustrates a width 218 of the second pillar 186 and the third pillar 188. The width 216 is smaller than the width 218. FIGS. 22A, 22B, and 22C are drawings in which the eddy current sensor 210 illustrated in FIG. 21 is viewed from above. FIGS. 22A, 22B, and 22C illustrate only positions of the correction coil 166, the excitation coil 164, and the detection coil 34, respectively, when they are viewed from above. FIG. 23 illustrates the magnetic field 212 of the embodiment illustrated in FIG. 21. Since the excitation coil 164 is arranged at a position close to the polishing object 102, a strong magnetic field is generated in the polishing object 102. With the embodiment, since the excitation coil 164 and the detection coil 34 are disposed near the polishing surface together, the detection sensitivity can be maximized.

Note that, while in the above description, one embodiment of the present invention when the magnetic material is an E-type core and when the magnetic material is a pod-shape core has been described, the magnetic material of the present invention is not limited to an E-type core and a pod-shape core. The magnetic material may be in one bar shape. The shape of the bar may be any shape, such as a columnar shape, a prism shaped, and an elliptic cylinder. For example, when the magnetic material is in a columnar shape, the detection coil 34, the excitation coil 164, and the correction coil 166 may be wound around one column. The detection coil 34, the excitation coil 164, and the correction coil 166 may be disposed in the order on the one column from a position close to the polishing object 102 to a position far from the polishing object 102. In order to adjust the sensitivity, for example, the number of turns of the detection coil 34 is made more than the number of turns of the correction coil 166.

Next, the end point detector 240 and the polishing apparatus controller 140 illustrated in FIG. 1 are described. The end point detector 240 receives the film thickness data 150 obtained by the detected signal processing circuit 220. The end point detector 240 monitors the end point of polishing based on the change in the film thickness data 150. The end point detector 240 can detect the end point of polishing by the film thickness data 150 reaching a predetermined value.

The end point detector 240 is connected to the polishing apparatus controller 140 that performs various kinds of controls relating to the polishing apparatus 100. Upon detecting the end point of polishing of the polishing object 102 based on the film thickness data 150, the end point detector 240 outputs a signal indicating such to the polishing apparatus controller 140. The polishing apparatus controller 140 terminates polishing by the polishing apparatus 100 upon receiving the signal indicating the end point of polishing from the end point detector 240.

The eddy current sensor assembly as one embodiment of the present invention has the eddy current sensor 210 and the impedance converter 124 or the amplifier.

The operations of the embodiments of the present invention are possible to be performed by using the following software and/or system. For example, the system (the polishing apparatus 100) includes a main controller (the polishing apparatus controller 140) that controls the whole body, and a plurality of sub-controllers that respectively control operations of respective devices (the drivers 112, 118, the holder 116, the detected signal processing circuit 220). The main controller and the sub-controllers respectively have a CPU, a memory, a recording medium, and software (program) stored in the recording medium for operating the respective devices.

While the examples of the embodiments of the present invention have been described above, the embodiments of the present invention described above are for easily understanding the present invention, and are not for limiting the present invention. The present invention may be changed and modified without departing from its gist, and the present invention obviously includes the equivalents thereof. Within the range in which at least a part of the above-described problems is solvable or the range in which at least a part of the effects is achieved, any combination or omission of each of the components described in the claims and the description are allowed.

### REFERENCE SIGNS LIST

34 . . . detection coil
100 . . . polishing apparatus
102 . . . polishing object
108 . . . polishing pad
110 . . . polishing table
116 . . . top ring
122 . . . analog-digital conversion circuit
124 . . . impedance converter
150 . . . film thickness data
154 . . . magnetic material
156 . . . bottom
158 . . . first pillar
162 . . . external wall
164 . . . excitation coil
166 . . . correction coil
186 . . . second pillar
188 . . . third pillar
194, 196 . . . magnetic field
200, 204, 206 . . . difference
210 . . . eddy current sensor
220 . . . detected signal processing circuit
240 . . . end point detector

1. An eddy current sensor comprising:
a magnetic material including a bottom, a first pillar extending from a center of the bottom, and an external wall extending from a periphery of the bottom;
an excitation coil wound to surround the first pillar and/or the external wall, the excitation coil configured to generate an eddy current in a conductive film; and
a detection coil and a correction coil wound to surround the first pillar and/or the external wall, the detection coil and the correction coil configured to detect a change in the eddy current generated in the conductive film, wherein
an amount of change in an output signal of the correction coil when the eddy current generated in the conductive film changes is less than an amount of change in an output signal of the detection coil, and
one end of the correction coil is directly connected to one end of the detection coil, and another end of the correction coil and another end of the detection coil are directly connected to an impedance converter or an amplifier.

2. The eddy current sensor according to claim 1, wherein
the detection coil has a cross-sectional area larger than a cross-sectional area of the correction coil, and/or the detection coil has a count of turns more than a count of turns of the correction coil, and/or a distance from the detection coil to the bottom is longer than a distance from the correction coil to the bottom.

3. The eddy current sensor according to claim 1, wherein
the external wall surrounds an outer periphery of the first pillar.

4. The eddy current sensor according to claim 1, wherein
the bottom is in a bar shape, and the external wall includes a second pillar and a third pillar disposed at respective both ends of the bar shape.

5. The eddy current sensor according to claim 1, wherein
the correction coil and the detection coil have winding directions in opposite directions.

6. The eddy current sensor according to claim 1, wherein
the excitation coil and the detection coil are both disposed in an opposite side of the bottom in a direction in which the first pillar extends.

7. The eddy current sensor according to claim 4, wherein
the correction coil is wound around the second pillar and the third pillar.

8. The eddy current sensor according to claim 7, wherein
the detection coil and the correction coil have winding directions in a same direction.

9. The eddy current sensor according to claim 1, wherein
the detection coil and the correction coil are configured of one continuous conductive line, a part of the one conductive line is the detection coil, and another part of the one conductive line is the correction coil.

10. An eddy current sensor assembly comprising:
the eddy current sensor according to claim 1; and
the impedance converter or the amplifier.

11. A polishing apparatus comprising:
a polishing pad having a polishing surface for polishing the conductive film;
a polishing table to which the polishing pad is mounted;
the eddy current sensor according to claim 1 disposed in the polishing table;
the impedance converter or the amplifier; and
a detected signal processing circuit configured to calculate film thickness data of the conductive material from an output of the impedance converter or the amplifier.
